(19) United States
(12) Patent Application Publication
(10) Pub. No.: US 2026/0040614 A1
(43) Pub. Date: Feb. 5, 2026

(54) SEMICONDUCTOR DEVICE

(71) Applicant: Sony Group Corporation, Tokyo (JP)

(72) Inventor: Tetsuya Ikuta, Kanagawa (JP)

(21) Appl. No.: 19/099,655

(22) PCT Filed: Jul. 28, 2023
(86) PCT No.: PCT/JP2023/027766

§ 371 Date: Jan. 29, 2025

(30) Foreign Application Priority Data
Aug. 26, 2022 (JP) 2022-134837

(51) Int. Cl. H10D 30/66; H10D 30/01; H10D 62/10; H10D 62/832

(52) U.S. Cl. CPC H10D 30/668; H10D 30/0297; H10D 62/127; H10D 62/8325

(57) ABSTRACT

A semiconductor device including a semiconductor substrate having a first surface on which a first electrode is disposed, a first semiconductor region, of a first conductivity type, disposed on a second surface of the semiconductor substrate, a plurality of second semiconductor regions, of a second conductivity type, disposed on the first semiconductor region and extending along a first direction, a third semiconductor region, of the second conductivity type, disposed on the first semiconductor region, the third semiconductor region defining a portion of a trench that extends along a second direction that traverses the first direction, a second electrode disposed in the trench, a first insulating film disposed in the trench and between a sidewall of the third semiconductor region defining the portion of the trench and the second electrode, and a fourth semiconductor region, of the first conductivity type, disposed on the third semiconductor region.

### CROSS REFERENCE TO RELATED APPLICATIONS

This application claims the benefit of Japanese Priority Patent Application JP 2022-134837 filed on Aug. 26, 2022, the entire contents of which are incorporated herein by reference.

### TECHNICAL FIELD

The present disclosure relates to a semiconductor device.

### BACKGROUND ART

In recent years, in order to cope with more various applications, there is an increasing demand for a high breakdown voltage transistor capable of handling a large current.

For example, PTL I below discloses a trench transistor having a drift layer between a channel formed on a side face of a gate electrode embedded vertically from a front face and a drain disposed on a back face. The trench transistor disclosed in PTL 1 can have a depletion layer in the thickness direction of the semiconductor substrate, so that high withstand voltage can be achieved.

### CITATION LIST

### Patent Literature

PTL 1: JP 2010-258328A

### SUMMARY OF INVENTION

### Technical Problem

However, in the trench transistor disclosed in PTL 1 described above, there has been a possibility that a high electric field is applied to the gate insulating film disposed on the bottom face of the gate electrode embedded in the vertical direction, thereby destroying the gate insulating film.

Therefore, in the trench transistor, it may be required to further improve reliability with respect to a high electric field.

### Solution to Problem

According to the present disclosure, there is provided a semiconductor device including a semiconductor substrate having a first surface on which a first electrode is disposed, a first semiconductor region, of a first conductivity type, disposed on a second surface of the semiconductor substrate, a plurality of second semiconductor regions, of a second conductivity type, disposed on the first semiconductor region and extending along a first direction, a third semiconductor region, of the second conductivity type, disposed on the first semiconductor region, the third semiconductor region defining a portion of a trench that extends along a second direction that traverses the first direction, a second electrode disposed in the trench, a first insulating film disposed in the trench and between a sidewall of the third semiconductor region defining the portion of the trench and the second electrode, and a fourth semiconductor region, of the first conductivity type, disposed on the third semiconductor region, wherein a first portion of the second electrode has a first depth that is shallower than a second depth of a second portion of the second electrode, and the second portion of the second electrode is closer to the second semiconductor region than the first portion of the second electrode. There is also provided a vehicle control system including an electronic controller including a semiconductor device, wherein the semiconductor device includes: a semiconductor substrate having a first surface on which a first electrode is disposed, a first semiconductor region, of a first conductivity type, disposed on a second surface of the semiconductor substrate, a plurality of second semiconductor regions, of a second conductivity type, disposed on the first semiconductor region and extending along a first direction, a third semiconductor region, of the second conductivity type, disposed on the first semiconductor region, the third semiconductor region defining a portion of a trench that extends along a second direction that traverses the first direction, a second electrode disposed in the trench, a first insulating film disposed in the trench and between a sidewall of the third semiconductor region defining the portion of the trench and the second electrode, and a fourth semiconductor region, of the first conductivity type, disposed on the third semiconductor region, wherein
a first portion of the second electrode has a first depth that is shallower than a second depth of a second portion of the second electrode, and the second portion of the second electrode is closer to the second semiconductor region than the first portion of the second electrode.

### BRIEF DESCRIPTION OF DRAWINGS

FIG. 1 is an explanatory view illustrating a planar configuration and a cross-sectional configuration of a semiconductor device according to the first configuration example.

FIG. 2 is an explanatory view illustrating a planar configuration and a cross-sectional configuration of a semiconductor device according to the second configuration example.

FIG. 3A is an explanatory view illustrating a step of a method for manufacturing a semiconductor device according to the second configuration example.

FIG. 3B is an explanatory view illustrating a step of the method for manufacturing a semiconductor device according to the second configuration example.

FIG. 3C is an explanatory view illustrating a step of the method for manufacturing a semiconductor device according to the second configuration example.

FIG. 3D is an explanatory view illustrating a step of the method for manufacturing a semiconductor device according to the second configuration example.

FIG. 3E is an explanatory view illustrating a step of the method for manufacturing a semiconductor device according to the second configuration example.

FIG. 3F is an explanatory view illustrating a step of the method for manufacturing a semiconductor device according to the second configuration example.

FIG. 4 is an explanatory view illustrating a planar configuration and a cross-sectional configuration of a modification of a semiconductor device according to the first configuration example.

FIG. 5 is an explanatory view illustrating a planar configuration and a cross-sectional configuration of a modification of a semiconductor device according to the second configuration example.

FIG. 6 is a block diagram illustrating an example of a schematic configuration of a vehicle control system.

FIG. 7 is an explanatory diagram illustrating an example of installation positions of an outside-vehicle information detecting section and an imaging unit.

### Description of Embodiments

Hereinafter, preferred embodiments of the present disclosure will be described in detail with reference to the accompanying drawings. Note that, in the present specification and the drawings, components having substantially the same functional configuration are denoted by the same reference numerals, and redundant description is omitted.

Note that the description will be given in the following order.
1. Embodiment
1.1. First configuration example
1.2. Second configuration example
1.3. Manufacturing method
1.4. Modifications
2. Application Example

### 1. Embodiment

### (1.1. First Configuration Example)

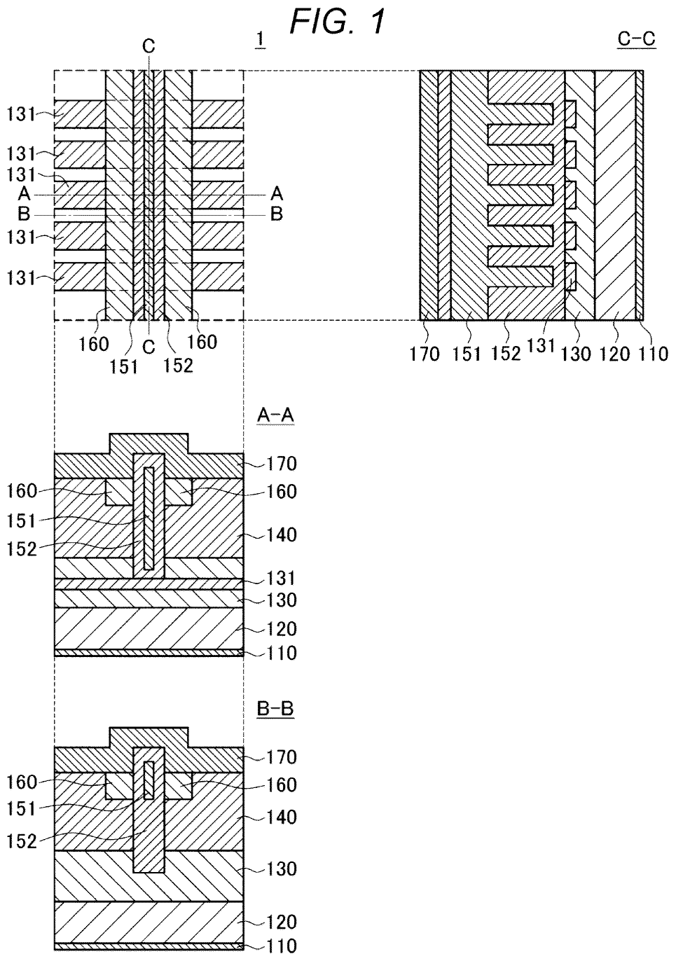

First, the first configuration example of a semiconductor device according to an embodiment of the present disclosure will be described with reference to FIG. 1. FIG. 1 is an explanatory view illustrating a planar configuration and a cross-sectional configuration of a semiconductor device 1 according to a first configuration example. The left middle, lower left, and upper right cross-sectional views of FIG. 1 show cross sections taken along lines A-A. B-B, or C-C, respectively, described in the upper left plan view.

As illustrated in FIG. 1, the semiconductor device 1 includes a first electrode 110, a semiconductor substrate 120, a first semiconductor region 130, a second semiconductor region 131, a third semiconductor region 140, a second electrode 151, a first insulating film 152, a fourth semiconductor region 160, and a third electrode 170. The semiconductor device 1 is a vertical metal oxide semiconductor field effect transistor (MOSFET) having a so-called trench structure.

In the upper left plan view of FIG. 1, the first electrode 110, the semiconductor substrate 120, the first semiconductor region 130, the third semiconductor region 140, and the third electrode 170 are omitted in order to clarify the arrangement of other configurations.

Hereinafter, the “first conductivity type” represents one of the “p-type” and the “n-type”, and the “second conductivity type” represents the other of the “p-type” and the “n-type” different from the “first conductivity type”.

The first electrode 110 includes a conductive material, and is disposed on the first principal surface of the semiconductor substrate 120. The first electrode 110 functions as a drain electrode of a vertical MOSFET by being electrically connected to the semiconductor substrate 120 via an ohmic junction or the like. The first electrode 110 may include, for example, copper (Ca), nickel (Ni), aluminum (Al), titanium (Ti), tantalum (Ta), tungsten (W), gold (Au), silver (Ag), or a combination of these metals.

The semiconductor substrate 120 is a substrate including a semiconductor material of the first conductivity type. For example, the semiconductor substrate 120 may be an n⁺-type SiC substrate. Note that the thickness of the semiconductor substrate 120 may be 100 μm to 350 μm. The concentration of the first conductivity type impurity (for example, nitrogen (N) or phosphorus (P)) of the semiconductor substrate 120 may be about 1.0×10¹⁸ cm⁻³ to 3.0×10¹⁹ cm⁻³.

The first semiconductor region 130 includes a semiconductor material of the first conductivity type, and is disposed on the upper face of the semiconductor substrate 120. For example, the first semiconductor region 130 may include n⁻-type SiC. The concentration of the first conductivity type impurity (for example, nitrogen (N) or phosphorus (P)) in the first semiconductor region 130 may be about 5.0×10¹⁵ cm⁻³ to 1.2×10¹⁶ cm⁻³.

The second semiconductor region 131 includes a semiconductor material of the second conductivity type, and a plurality of the second semiconductor regions is disposed to extend in the first direction (for example, in the left-right direction when viewing FIG. 1 from the front) inside the first semiconductor region 130. Specifically. the second semiconductor regions 131 are disposed in a stripe shape extending in the first direction in the first semiconductor region 130 in parallel to each other. With this arrangement, at the depth at which the second semiconductor regions 131 are disposed, the second semiconductor regions 131 and the first semiconductor regions 130 are alternately disposed in a stripe shape in the second direction (for example, in the vertical direction when viewing FIG. 1 from the front) orthogonal to the first direction. For example, the second semiconductor region 131 may include p-type SiC. In addition, the second semiconductor region 131 may be equipotential to the third semiconductor region 140 by being electrically connected to the third semiconductor region 140 by wiring (not illustrated).

Since the second semiconductor region 131 is of the second conductivity type, it is possible to prevent a high electric field from being applied to a region in the vicinity of the first insulating film 152. In addition, a depletion layer is formed to extend from the second semiconductor region 131 in the first semiconductor region 130 existing between the second semiconductor regions 131. Therefore, with the depletion layer. the second semiconductor region 131 can prevent a high electric field from being applied even to a non-vicinity region that is a region other than a region in the vicinity of the first insulating film 152. Therefore, the second semiconductor region 131 can suppress breakage of the first insulating film 152 due to a high electric field.

The concentration of the second conductivity type impurity (for example, aluminum (Al)) in the second semiconductor region 131 is set such that the first semiconductor region 130 existing between the second semiconductor regions 131 is not completely depleted by the voltage applied to the first electrode 110 during the normal operation. For example, the concentration of the second conductivity type impurity in the second semiconductor region 131 may be set to about 1.0×10¹⁸ cm⁻³ to 3.0×10¹⁹ cm⁻³. With this arrangement, even when the depletion layer spreads from the second semiconductor region 131, the first semiconductor region 130 can secure a current path passing between the second semiconductor regions 131 in the first semiconductor region 130.

The third semiconductor region 140 includes a semiconductor material of the second conductivity type, and is disposed on the first semiconductor region 130. For example, the third semiconductor region 140 may include p-type SiC. The concentration of the second conductivity type impurity (for example, aluminum (Al) in the third semiconductor region 140 may be about 1.0×10¹⁶ cm⁻³ to 5.0×10¹⁷ cm⁻³.

The second electrode 151 includes a conductive material, and is disposed as a trench type electrode embedded from the third semiconductor region 140 to the third semiconductor region 140. Specifically, the second electrode 151 may be disposed so as to be embedded in a trench disposed extending in the second direction (for example, in the vertical direction when viewing FIG. 1 from the front) orthogonal to the first direction in the third semiconductor region 140. The second electrode 151 may include, for example, poly-Si into which a conductivity type impurity is introduced. The second electrode 151 can function as a gate electrode of the semiconductor device 1.

The second electrode 151 is embedded in a region in the vicinity of the second semiconductor region 131 so as to reach the first semiconductor region 130, and is embedded to a depth that is shallower and does not reach the first semiconductor region 130 in a region not in the vicinity of the second semiconductor region 131. More specifically, the second electrode 151 may be embedded so as to reach the first semiconductor region 130 in a region in the vicinity immediately above the second semiconductor region 131, and may be embedded to a depth that is shallower and does not reach the first semiconductor region 130 in a region other than the vicinity immediately above the second semiconductor region 131. For example, in order not to form an inversion layer in the third semiconductor region 140 on the side face, the second electrode 151 in the non-vicinity region may be embedded to a depth similar to a depth at which the fourth semiconductor region 160 is disposed. With this arrangement, the second electrode 151 is disposed such that the extending cross section in the second direction has a comb teeth shape.

The first insulating film 152 includes an insulating material, and is disposed between the side face of the trench in which the second electrode 151 is disposed and the second electrode 151. Specifically, the first insulating film 152 may extend in the second direction between the side face and the bottom face of the trench and the second electrode 151 and be embedded in the third semiconductor region 140. The first insulating film 152 may include, for example, silicon oxide (SiOₓ)).

In a region in the vicinity of the second semiconductor region 131, the first insulating film 152 may be embedded to a depth in contact with the second semiconductor region 131 in order to more efficiently obtain the effect of electric field blocking by the second semiconductor region 131. In addition, in a region not in the vicinity of the second semiconductor region 131, the first insulating film 152 may be embedded to a depth same as a depth of a region in the vicinity thereof in order to simplify the manufacturing process.

The fourth semiconductor region 160 is a semiconductor region of the first conductivity type, and is disposed in the third semiconductor region 140. Specifically, the fourth semiconductor region 160 may be disposed in the third semiconductor region 140 on both sides of the second electrode 151 so as to sandwich a trench extending in the second direction orthogonal to the first direction. More specifically, the fourth semiconductor region 160 may extend in the second direction on the upper face of the third semiconductor region 140 while sandwiching a trench extending in the second direction orthogonal to the first direction. For example, the fourth semiconductor region 160 may be an n⁺-type SiC region. The concentration of the first conductivity type impurity (for example, nitrogen (N) or phosphorus (P)) in the fourth semiconductor region 160 may be about 7.0×10₁₈ cm⁻³ to 7.0×10 cm⁻³.

The third electrode 170 includes a conductive material, and is disposed on the third semiconductor region 140. The third electrode 170 functions as a source electrode of a vertical MOSFET by being electrically connected to the fourth semiconductor region 160 via an ohmic junction or the like. The third electrode 170 may include, for example, copper (Cu), nickel (Ni). aluminum (Al), titanium (Ti), tantalum (Ta), tungsten (W), gold (Au), silver (Ag), or a combination of these metals.

In the semiconductor device 1, when a voltage is applied to the second electrode 151 to be turned on, an inversion layer is formed in the third semiconductor region 140 on the side face of the second electrode 151, and a channel serving as a current path is formed. With this arrangement, since the fourth semiconductor region 160 and the first semiconductor region 130 are electrically connected to each other, the semiconductor device 1 can flow a current between the third electrode 170 and the first electrode 110. On the other hand, in the semiconductor device 1. the application of the voltage to the second electrode 151 is stopped and is turned off, so that the channel formed in the third semiconductor region 140 on the side face of the second electrode 151 is lost. With this arrangement, since the fourth semiconductor region 160 and the first semiconductor region 130 are non-conductive, the semiconductor device I can stop the flow of current between the third electrode 170 and the first electrode 110.

The semiconductor device 1 according to the present embodiment can prevent a high electric field from being applied to the first insulating film 152 by providing the second semiconductor region 131 in a region in the vicinity of the first insulating film 152 disposed between the trench and the second electrode 151. In addition, in the semiconductor device 1, when the second semiconductor region 131 and the second electrode 151 extend in directions orthogonal to each other, the second electrode 151 can be more easily positioned in a region in the vicinity of the second semiconductor region 131.

Further, in the semiconductor device I according to the present embodiment, an embedment depth of the second electrode 151 in a region not in the vicinity of the second semiconductor region 131 is configured to be shallower than an embedment depth of the second electrode 151 in a region in the vicinity thereof. With this arrangement, since the semiconductor device I can reduce the volume between the second electrode 151 and the first electrode 110 in the non-vicinity region, the switching characteristics can be further improved.

Furthermore, in the semiconductor device 1, the second electrode 151 is configured such that no channel is formed in a region not in the vicinity of the second semiconductor region 131. With this arrangement, the semiconductor device I can reduce the amount of saturation current flowing at the time of failure. In addition, since the semiconductor device 1 can avoid application of a voltage to the first insulating film 152 in the non-vicinity region, the withstand voltage of the first insulating film 152 can be further improved.

### (1.2. Second Configuration Example)

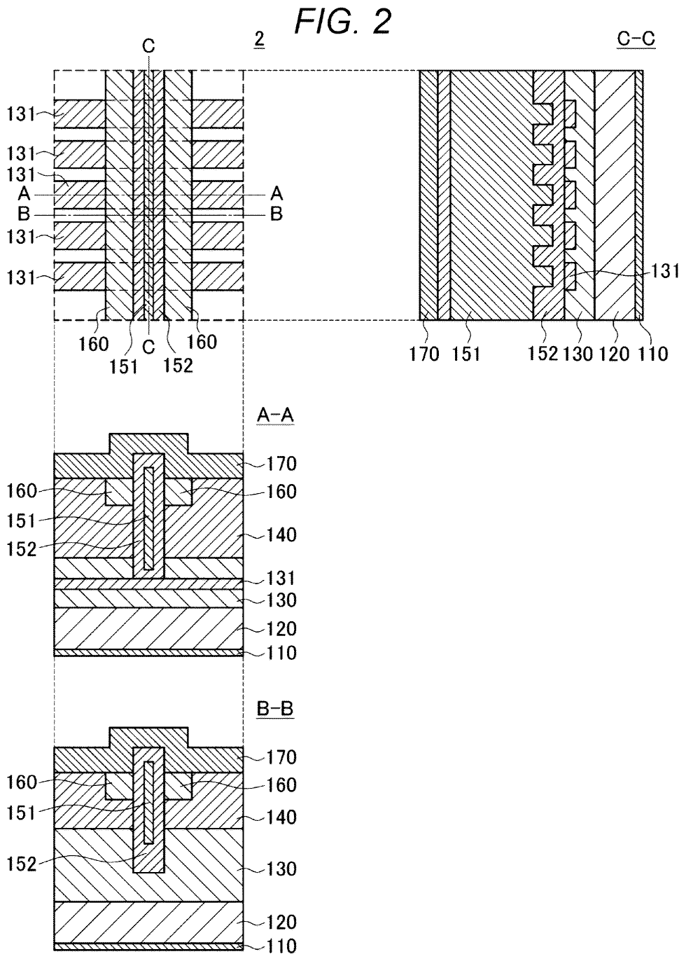

Next, the second configuration example of the semiconductor device according to the present embodiment will be described with reference to FIG. 2. FIG. 2 is an explanatory view illustrating a planar configuration and a cross-sectional configuration of a semiconductor device 2 according to the second configuration example. The left middle, lower left, and upper right cross-sectional views of FIG. 2 show cross sections taken along lines A-A, B-B, or C-C, respectively, described in the upper left plan view.

As illustrated in FIG. 2, the semiconductor device 2 is disposed such that the ratio of the thicknesses of the first semiconductor region 130 and the third semiconductor region 140 is different between a region in the vicinity of and a region not in the vicinity of the second semiconductor region 131. With this arrangement, the semiconductor device 2 can form the inversion layer and the channel in the third semiconductor region 140 on the side face of the second electrode 151 even in the region not in the vicinity of the second semiconductor region 131.

Specifically, the first semiconductor region 130 is disposed so as to be thicker in the region not in the vicinity of the second semiconductor region 131 than in the region in the vicinity thereof, and the third semiconductor region 140 is disposed so as to be thinner in the non-vicinity region than in the vicinity region. That is, the interface between the first semiconductor region 130 and the third semiconductor region 140 has a periodic projection-recess shape in the second direction in a region in the vicinity of and a region not in the vicinity of the second semiconductor region 131.

With this arrangement, the second electrode 151 in the non-vicinity region disposed such that the embedment depth is shallower than that in the vicinity region can reach the first semiconductor region 130. Therefore, the second electrode 151 in the non-vicinity region can form an inversion layer in the third semiconductor region 140 on the side face by voltage application to form a channel serving as a current path between the fourth semiconductor region 160 and the first semiconductor region 130.

The semiconductor device 2 according to the second configuration example can have a channel serving as a current path not only in the region in the vicinity of the second semiconductor region 131 but also in the region not in the vicinity thereof, so that the on-resistance can be further reduced.

### (1.3. Manufacturing Method)

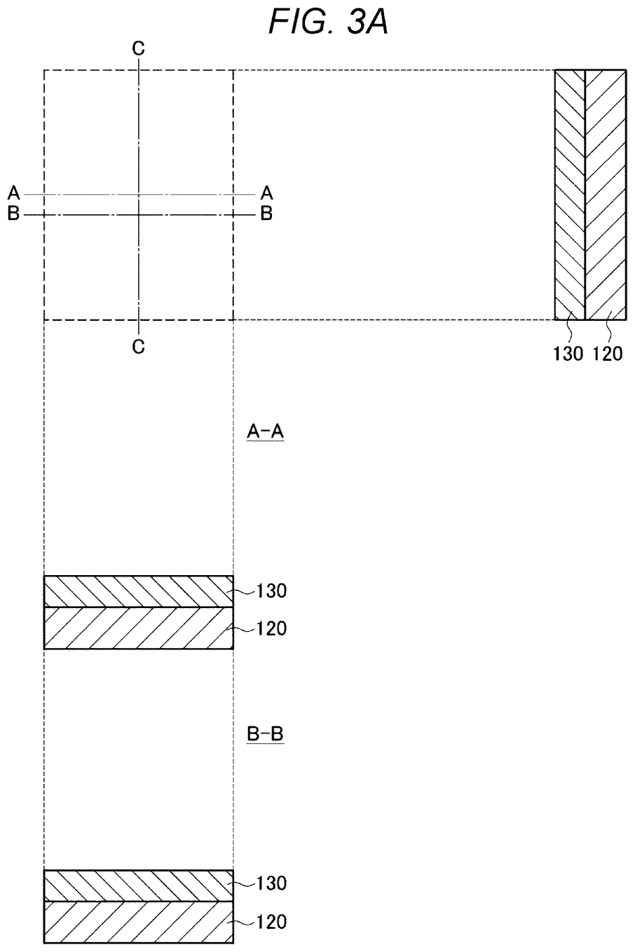

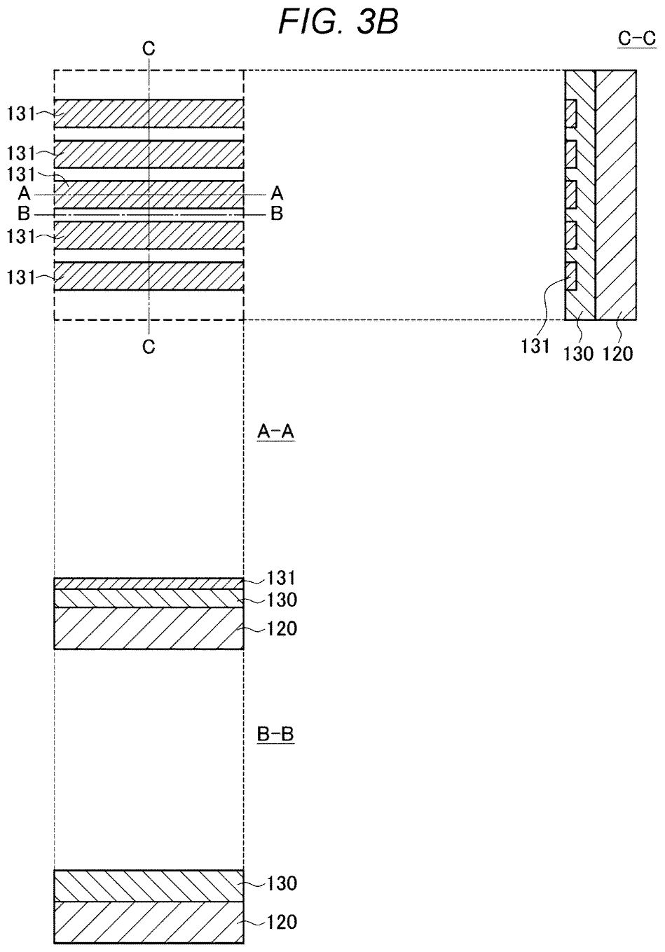

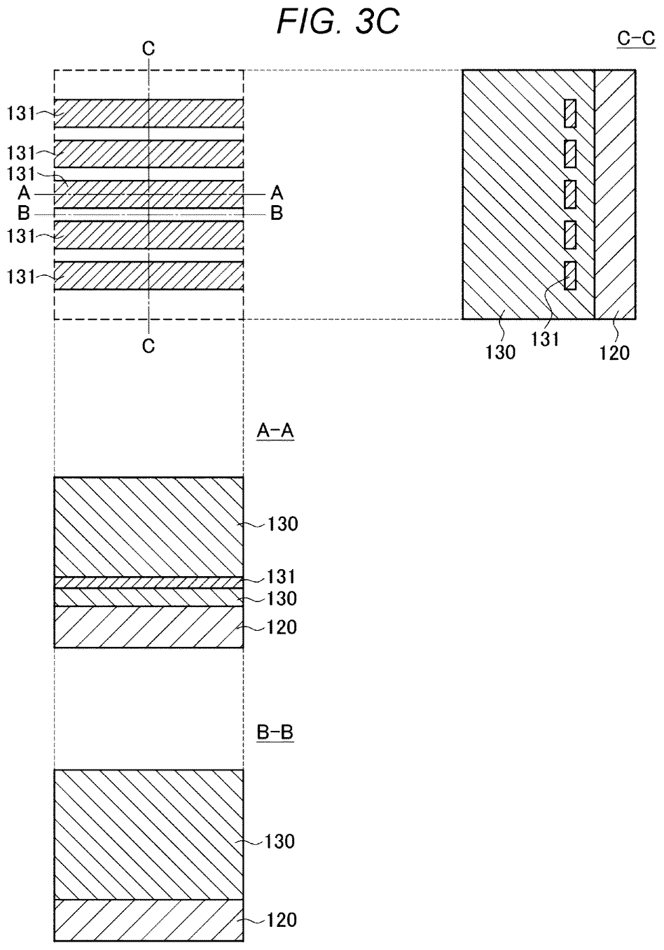

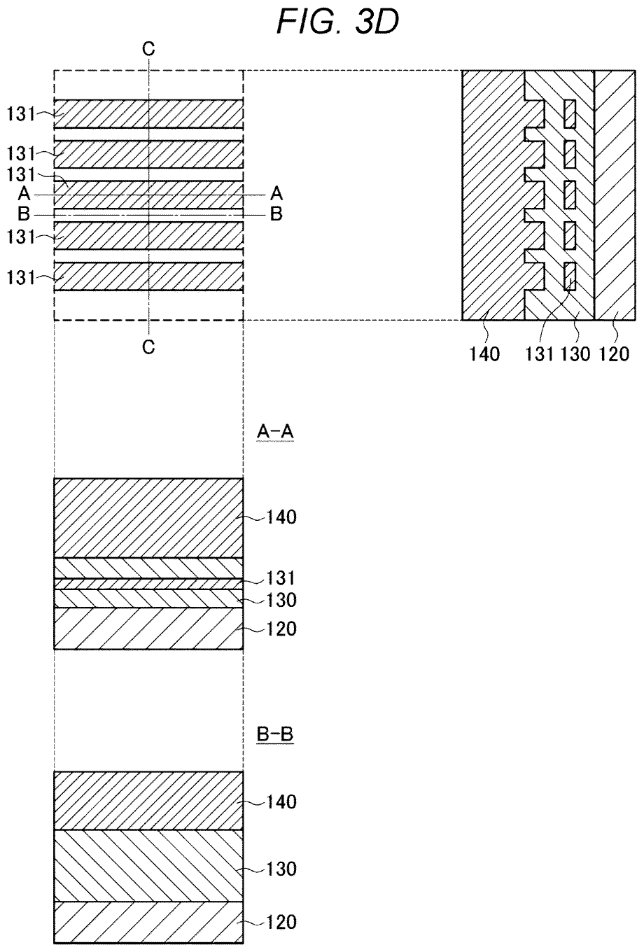

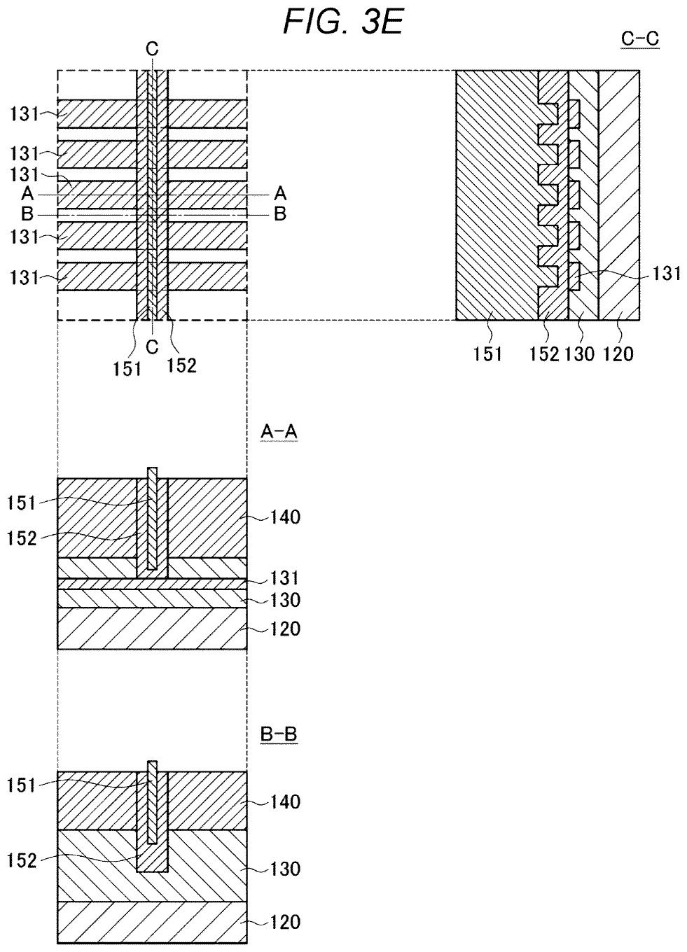

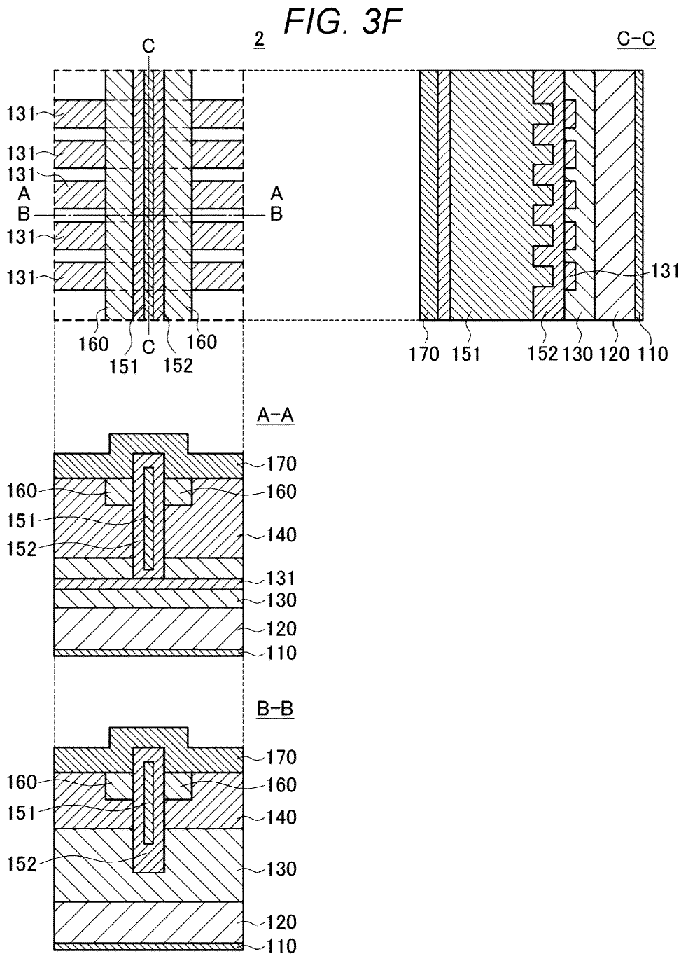

Next, a method of manufacturing the semiconductor device 2 according to the second configuration example will be described with reference to FIGS. 3A to 3F. FIGS. 3A to 3F are explanatory diagrams illustrating a step of a method for manufacturing the semiconductor device 2 according to the second configuration example. The left middle, lower left, and upper right cross-sectional views of FIGS. 3A to 3E show cross sections taken along lines A-A, B-B, or C-C, respectively, described in the upper left plan view.

As illustrated in FIG. 3A, first. SiC is deposited on the second principal surface of the semiconductor substrate 120 while nitrogen (N) serving as a first conductivity type impurity is introduced using a chemical vapor deposition (CVD) method, thereby forming the first semiconductor region 130. As the semiconductor substrate 120, for example, an n+-type SiC substrate formed by a sublimation method may be used.

Next, as illustrated in FIG. 3B. aluminum (Al) serving as a second conductivity type impurity is introduced into the first semiconductor region 130 by about 200 nm to 500 mm using ion implantation, and then annealing is performed at about 1800° C. for several hours. whereby the second semiconductor region 131 is formed in the first semiconductor region 130. For example, a plurality of second semiconductor regions 131 may be formed in a stripe shape so as to extend in parallel to each other in the first direction (for example, in the left-right direction when viewing FIG. 3B from the front).

Subsequently, as illustrated in FIG. 3C. SiC is deposited on the second semiconductor region 131 while nitrogen (N) serving as the first conductivity type impurity is introduced using the CVD method, whereby the first semiconductor region 130 is further formed.

Thereafter, as illustrated in FIG. 3D, aluminum (Al) serving as a second conductivity type impurity is introduced into the upper portion of the first semiconductor region 130 by ion implantation, and then annealing is performed at about 1800° C. for several hours, whereby the upper portion of the first semiconductor region 130 is converted into the third semiconductor region 140.

At this time, the ratio of the thicknesses of the first semiconductor region 130 and the third semiconductor region 140 may be changed by changing the implantation depth of the second conductivity type impurity between a region in the vicinity of and a region not in the vicinity of the second semiconductor region 131. For example, the third semiconductor region 140 may be formed such that a region in the vicinity of the second semiconductor region 131 has a larger thickness than a non-vicinity region.

Subsequently, as illustrated in FIG. 3E, a trench formed by etching the third semiconductor region 140 and the first semiconductor region 130 is surface-oxidized, and then the trench is filled with poly-Si into which a conductive type impurity is introduced, thereby forming the first insulating film 152 and the second electrode 151.

Specifically, first, a trench is formed by etching the third semiconductor region 140 and the first semiconductor region 130 in a region extending in the second direction (for example, in the vertical direction when viewing FIG. 3E from the front) using a hard mask until the second semiconductor region 131 is exposed. Next, after the trench in the region not in the vicinity of the second semiconductor region 131 is partially filled with silicon oxide (SiOₓ), the embedded SiOₓ is etched to a desired height in the vicinity of the interface between the third semiconductor region 140 and the first semiconductor region 130. Next, after the SiC at the bottom face and the side face of the trench is oxidized, an interface modification process is performed with a nitrogen monoxide (NO) gas, whereby the first insulating film 152 including silicon oxide (SiOₓ) is formed. Subsequently, the remaining portion of the trench is filled with poly-Si into which a conductive type impurity is introduced, thereby forming the second electrode 151.

Thereafter, as shown in FIG. 3F, the fourth semiconductor region 160 is formed in the third semiconductor region 140 by ion implantation, and then the third electrode 170 and the first electrode 110 are formed. Note that the third semiconductor region 140 may further have a contact region of the second conductivity type using ion implantation in order to reduce the contact resistance between the third semiconductor region 140 and the third electrode 170.

Specifically, first, nitrogen (N) serving as the first conductivity type impurity is introduced into the third semiconductor region 140 on both sides of the trench extending in the second direction orthogonal to the first direction by ion implantation, whereby the fourth semiconductor region 160 is formed. Next, the second electrode 151 is protected with an insulating layer, and then nickel (Ni) and aluminum (Al) sequentially deposited on the upper face of the third semiconductor region 140 are patterned to form the third electrode 170 electrically connected to the fourth semiconductor region 160. Subsequently, nickel (Ni), titanium (Ti), nickel (Ni), and gold (Au) are sequentially deposited on the first principal surface of the semiconductor substrate 120, thereby forming the first electrode 110 electrically connected to the semiconductor substrate 120.

Through the above steps. the semiconductor device 2 according to the present embodiment is manufactured.

### (1.4. Modifications)

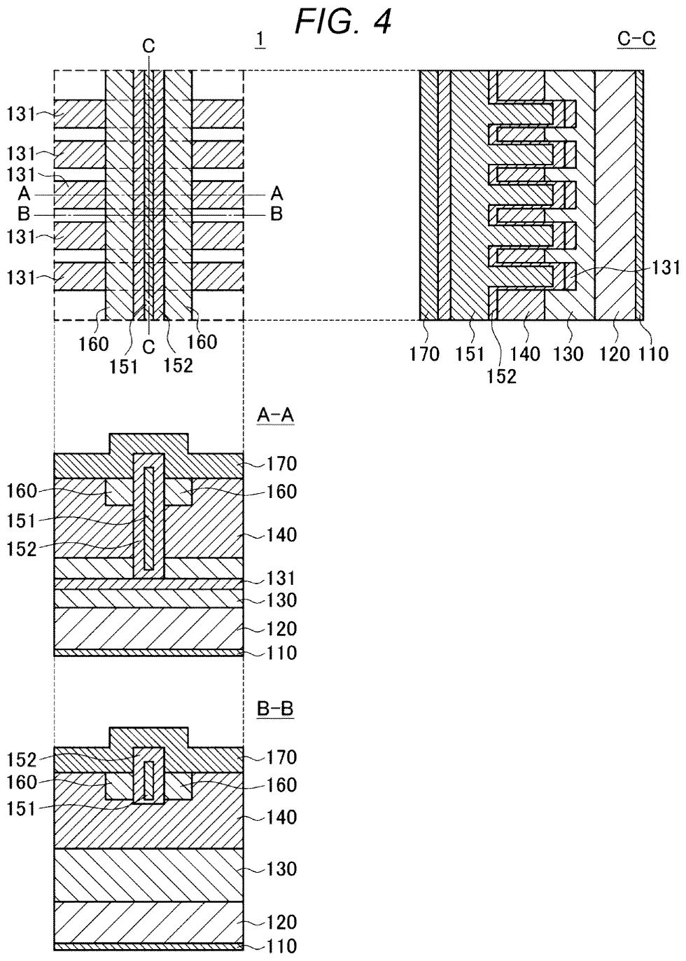

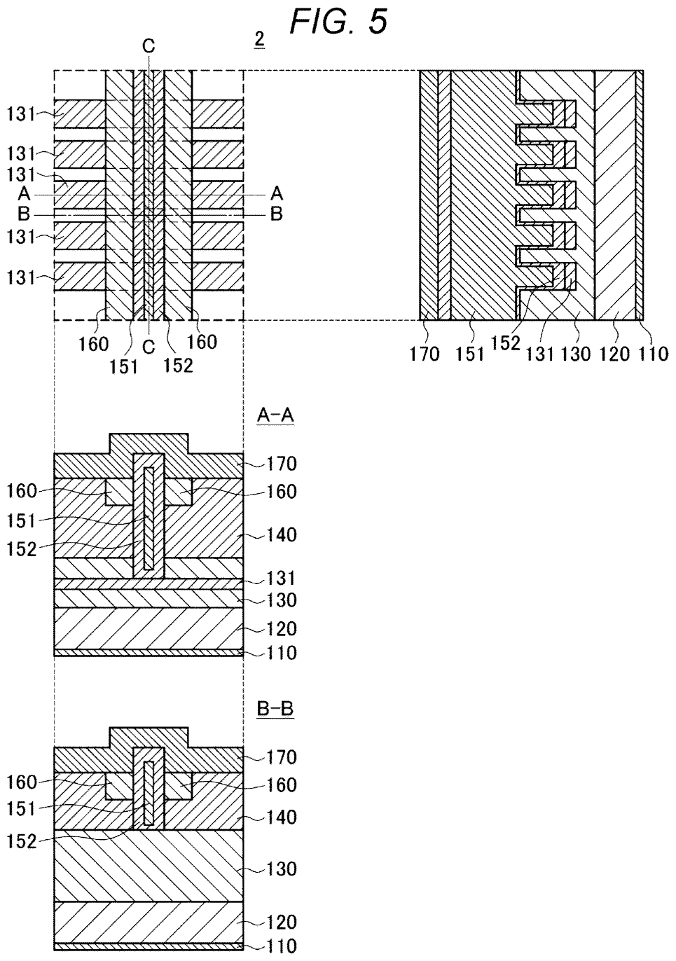

Furthermore. a modification of the semiconductor device according to the present embodiment will be described with reference to FIGS. 4 and 5. FIG. 4 is an explanatory view illustrating a planar configuration and a cross-sectional configuration of a modification of the semiconductor device I according to the first configuration example. FIG. 5 is an explanatory view illustrating a planar configuration and a cross-sectional configuration of a modification of the semiconductor device 2 according to the second configuration example.

As illustrated in FIGS. 4 and 5, the first insulating film 152 may be disposed by changing the depth of the first insulating film 152 that is embedded in each of a region in the vicinity of and a region not in the vicinity of the second semiconductor region 131. Specifically, the first insulating film 152 may be disposed such that the embedment depth in the non-vicinity region is shallower than the embedment depth in the vicinity region, corresponding to the embedment depth of the second electrode 151.

For example, as illustrated in FIG. 4, in the semiconductor device I according to the first configuration example, the first insulating film 152 may be embedded in the vicinity region so as to reach the second semiconductor region 131, while may be embedded in the non-vicinity region so as to be shallower at a depth same as that of the fourth semiconductor region 160. With this arrangement, in the semiconductor device 1. it is not necessary to backfill the trench in the non-vicinity region of the trench formed in the third semiconductor region 140 and the first semiconductor region 130 with the insulating material, and thus, it is possible to further simplify the manufacturing process.

Even in such a case, since the semiconductor device I can reduce the volume between the second electrode 151 and the first electrode 110 in the non-vicinity region. the switching characteristics can be further improved. In addition, in the semiconductor device 1, it is possible not to have a channel in the third semiconductor region 140 on the side face of the second electrode 151 in the non-vicinity region, so that the amount of saturation current flowing at the time of failure can be reduced.

For example, as illustrated in FIG. 5, in the semiconductor device 2 according to the second configuration example, the first insulating film 152 may be embedded in the vicinity region so as to reach the second semiconductor region 131, while may be embedded in the non-vicinity region so as to reach the interface of the first semiconductor region 130 disposed shallower. With this arrangement, the semiconductor device 2 can control the etching end point of the trench in a self-aligned manner using the interface between the third semiconductor region 140 and the first semiconductor region 130. Therefore. the process of manufacturing the semiconductor device 2 can be further simplified.

Even in such a case, since the semiconductor device 2 can reduce the volume between the second electrode 151 and the first electrode 110 in the non-vicinity region, the switching characteristics can be further improved. In addition, since the semiconductor device 2 can have a channel serving as a current path not only in the region in the vicinity of the second semiconductor region 131 but also in the region not in the vicinity thereof, so that the on-resistance can be further reduced.

### 2. Application Example

The technology according to the present disclosure can be applied to various products. For example, the technology according to the present disclosure may be realized as a device mounted on any type of moving body such as an automobile, an electric vehicle, a hybrid electric vehicle, a motorcycle, a bicycle, a personal mobility, an airplane, a drone, a ship, a robot, a construction machine, or an agricultural machine (tractor).

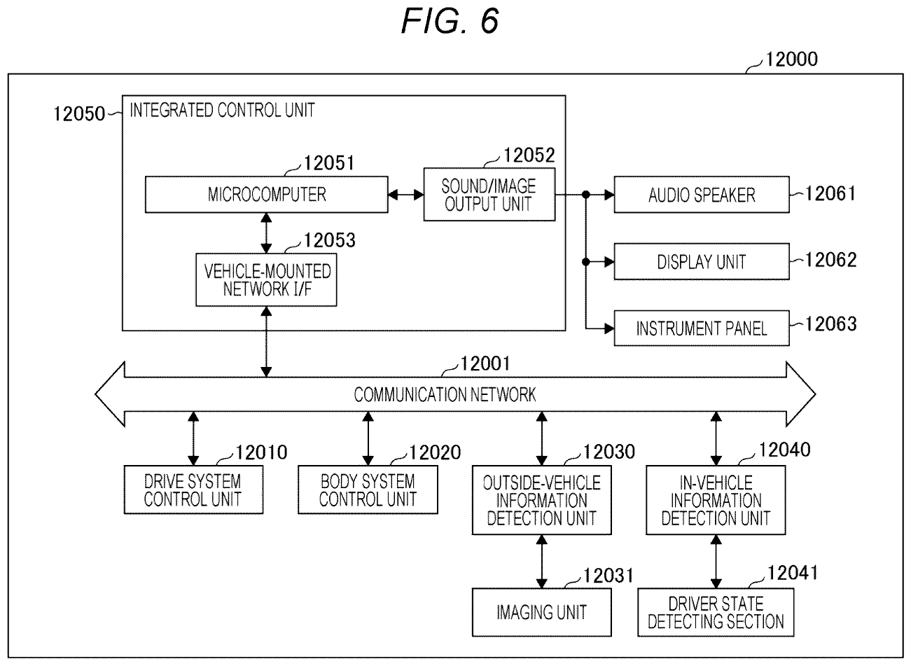

FIG. 6 is a block diagram illustrating a schematic configuration example of a vehicle control system which is an example of a moving body control system to which the technology according to the present disclosure can be applied.

A vehicle control system 12000 includes a plurality of electronic control units connected via a communication network 12001. In the example illustrated in FIG. 6, the vehicle control system 12000 includes a drive system control unit 12010, a body system control unit 12020, an outside-vehicle information detection unit 12030, an in-vehicle information detection unit 12040, and an integrated control unit 12050. Furthermore, as a functional configuration of the integrated control unit 12050, a microcomputer 12051, a sound/image output unit 12052, and a vehicle-mounted network interface (I/F) 12053 are illustrated.

The drive system control unit 12010 controls the operation of devices related to the drive system of the vehicle according to various kinds of programs. For example, the drive system control unit 12010 serves as a driving force generation device that generates the driving force of the vehicle such as an internal combustion engine or a driving motor, a driving force transmitting mechanism that transmits the driving force to the wheels, a steering mechanism for adjusting a steering angle of the vehicle, and a control device such as a braking device that generates a braking force of the vehicle.

The body system control unit 12020 controls operations of various kinds of devices mounted on the vehicle body according to various kinds of programs. For example, the body system control unit 12020 functions as a control device of a keyless entry system, a smart key system, a power window device, or various lamps such as a head lamp, a backup lamp, a brake lamp, a blinker, or a fog lamp. In this case, radio waves transmitted from a portable device that substitutes for a key or signals of various switches can be input to the body system control unit 12020. The body system control unit 12020 receives input of these radio waves or signals, and controls a door lock device, a power window device, a lamp, and the like of the vehicle.

The outside-vehicle information detection unit 12030 detects information outside the vehicle on which the vehicle control system 12000 is mounted. For example, an imaging unit 12031 is connected to the outside-vehicle information detection unit 12030. The outside-vehicle information detection unit 12030 causes the imaging unit 12031 to capture an image of the outside of the vehicle, and receives the captured image. The outside-vehicle information detection unit 12030 may perform object detection processing or distance detection processing of a person, a vehicle, an obstacle, a sign, a character on a road surface, or the like on the basis of the received image.

The imaging unit 12031 is an optical sensor that receives light to output an electric signal corresponding to the amount of received light. The imaging unit 12031 can output the electric signal as an image and can output the electric signal as distance measurement information. Furthermore. the light received by the imaging unit 12031 may be visible light or invisible light such as infrared rays.

The in-vehicle information detection unit 12040 detects information inside the vehicle. For example, a driver state detecting section 12041 that detects a state of a driver is connected to the in-vehicle information detection unit 12040. The driver state detecting section 12041 includes, for example, a camera that images the driver, and the in-vehicle information detection unit 12040 may calculate the degree of fatigue or the degree of concentration of the driver or may determine whether or not the driver is dozing off on the basis of the detection information input from the driver state detecting section 12041.

The microcomputer 12051 can calculate a control target value of the driving force generation device, the steering mechanism, or the braking device on the basis of the information inside and outside the vehicle acquired by the outside-vehicle information detection unit 12030 or the in-vehicle information detection unit 12040, and output a control command to the drive system control unit 12010. For example, the microcomputer 12051 can perform cooperative control for the purpose of implementing functions of an advanced driver assistance system (ADAS) including collision avoidance or impact mitigation of the vehicle, following driving based on an inter-vehicle distance, vehicle speed maintenance traveling, warning of collision of a vehicle, vehicle lane departure warning, or the like.

Furthermore, the microcomputer 12051 can control the driving force generation device, the steering mechanism, the braking device, or the like on the basis of the information around the vehicle acquired by the outside-vehicle information detection unit 12030 or the in-vehicle information detection unit 12040, thereby performing cooperative control for the purpose of automated driving or the like in which the vehicle autonomously travels without depending on the operation of the driver.

Furthermore, the microcomputer 12051 can output a control command to the body system control unit 12020 on the basis of the outside-vehicle information acquired by the outside-vehicle information detection unit 12030. For example, the microcomputer 12051 can perform cooperative control for the purpose of preventing glare, such as switching from a high beam to a low beam, by controlling the head lamp according to the position of a preceding vehicle or an oncoming vehicle detected by the outside-vehicle information detection unit 12030.

The sound/image output unit 12052 transmits an output signal of at least one of a sound or an image to an output device capable of visually or audibly notifying an occupant of the vehicle or the outside of the vehicle of information. In the example of FIG. 6, an audio speaker 12061, a display unit 12062, and an instrument panel 12063 are illustrated as the output device. The display unit 12062 may include, for example, at least one of an on-board display or a head-up display.

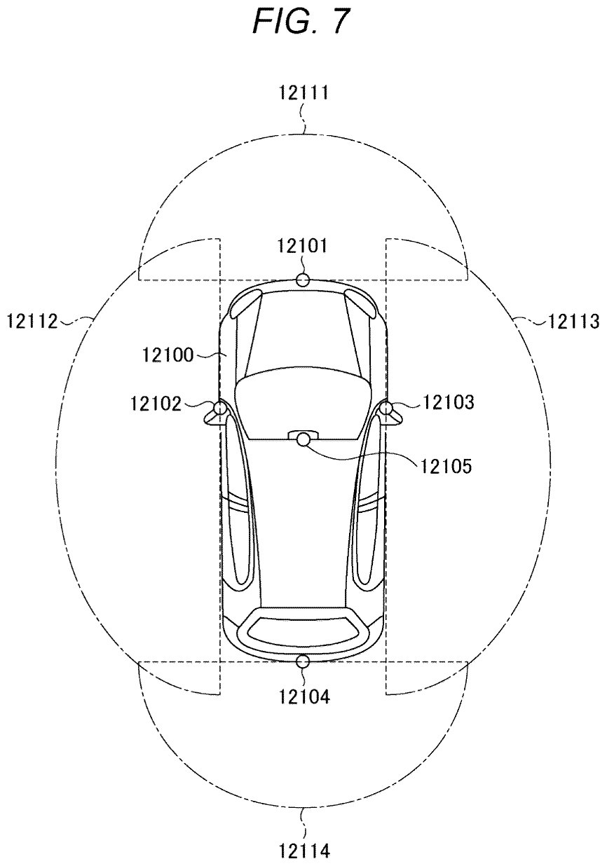

FIG. 7 is a diagram illustrating an example of an installation position of the imaging unit 12031.

In FIG. 7, imaging units 12101, 12102, 12103, 12104, and 12105 are included as the imaging unit 12031.

The imaging units 12101, 12102, 12103, 12104, and 12105 are disposed, for example, at positions such as a front nose, a sideview mirror, a rear bumper, a back door, and an upper portion of a windshield in a vehicle compartment of a vehicle 12100. The imaging unit 12101 disposed at the front nose and the imaging unit 12105 disposed at the upper portion of the windshield in the vehicle compartment mainly acquire images in front of the vehicle 12100. The imaging units 12102 and 12103 disposed at the sideview mirrors mainly acquire images of the sides of the vehicle 12100. The imaging unit 12104 disposed at the rear bumper or the back door mainly acquires an image behind the vehicle 12100. The imaging unit 12105 disposed at the upper portion of the windshield in the vehicle compartment is mainly used to detect a preceding vehicle, a pedestrian, an obstacle, a traffic light, a traffic sign, a lane, or the like.

Note that FIG. 7 illustrates an example of imaging ranges of the imaging units 12101 to 12104. An imaging range 12111 indicates an imaging range of the imaging unit 12101 disposed at the front nose, imaging ranges 12112 and 12113 indicate imaging ranges of the imaging units 12102 and 12103 disposed at the sideview mirrors, respectively, and an imaging range 12114 indicates an imaging range of the imaging unit 12104 disposed at the rear bumper or the back door. For example, by superimposing image data captured by the imaging units 12101 to 12104, a bird's-eye view image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging elements, or may be an imaging element having pixels for phase difference detection.

For example, the microcomputer 12051 obtains a distance to each three-dimensional object in the imaging ranges 12111 to 12114 and a temporal change in the distance (relative speed with respect to the vehicle 12100) on the basis of the distance information obtained from the imaging units 12101 to 12104, thereby extracting, as a preceding vehicle, a three-dimensional object traveling at a predetermined speed (for example. 0 km/h or more) in substantially the same direction as the vehicle 12100, in particular, the three-dimensional object closest to the vehicle 12100 on a traveling path of the vehicle 12100. Furthermore, the microcomputer 12051 can set an inter-vehicle distance to be secured in advance in front of the preceding vehicle, and can perform automatic brake control (including following stop control). automatic acceleration control (including following start control), and the like. As described above, it is possible to perform cooperative control for the purpose of automated driving or the like in which the vehicle autonomously travels without depending on the operation of the driver.

For example, on the basis of the distance information obtained from the imaging units 12101 to 12104, the microcomputer 12051 can classify three-dimensional object data regarding three-dimensional objects into a two-wheeled vehicle, a standard-sized vehicle, a large-sized vehicle, a pedestrian, and another three-dimensional object such as a utility pole, extract the three-dimensional objects, and use the three-dimensional objects for automatic avoidance of obstacles. For example, the microcomputer 12051 identifies obstacles around the vehicle 12100 as an obstacle that can be visually recognized by the driver of the vehicle 12100 and an obstacle that are difficult for the driver to visually recognize. Then, the microcomputer 12051 determines a collision risk indicating a risk level of collision with each obstacle, and when the collision risk is a setting value or more and there is a possibility of collision, the microcomputer 12051 can perform driving assistance for collision avoidance by outputting an alarm to the driver via the audio speaker 12061 or the display unit 12062 or performing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether or not a pedestrian is present in the captured images of the imaging units 12101 to 12104. Such recognition of the pedestrian is performed by, for example, a procedure of extracting feature points in the captured images of the imaging units 12101 to 12104 serving as infrared cameras, and a procedure of performing a pattern matching process on a series of feature points indicating an outline of an object to determine whether or not the object is a pedestrian. When the microcomputer 12051 determines that a pedestrian is present in the captured images of the imaging units 12101 to 12104 and recognizes the pedestrian, the sound/image output unit 12052 causes the display unit 12062 to superimpose and display a square contour line for emphasis on the recognized pedestrian. Furthermore, the sound/image output unit 12052 may cause the display unit 12062 to display an icon or the like indicating a pedestrian at a desired position.

An example of the vehicle control system to which the technology according to the present disclosure can be applied is described above. The technology according to the present disclosure can be applied to electronic control units such as the drive system control unit 12010, the body system control unit 12020, the outside-vehicle information detection unit 12030, the in-vehicle information detection unit 12040, and the integrated control unit 12050 among the above-described configurations. Specifically, each of the semiconductor device I according to the first configuration example or the semiconductor device 2 according to the second configuration example can be applied to a transistor included in the electronic control unit described above. The technology according to the present disclosure can further improve the withstand voltage and reliability of the transistor, and thus can be more preferably applied to a vehicle control system in which a higher voltage is used. According to the technology according to the present disclosure, the vehicle control system can improve the reliability of the system with respect to a high voltage and reduce the influence when the transistor fails.

Although the preferred embodiments of the present disclosure have been described in detail with reference to the accompanying drawings, the technical scope of the present disclosure is not limited to such examples. It is obvious that a person having ordinary knowledge in the technical field of the present disclosure can conceive various changes or modifications within the scope of the technical idea described in the claims, and it is naturally understood that these also belong to the technical scope of the present disclosure.

In addition, the effects described in the present specification are merely illustrative or exemplary, and are not restrictive. That is, the technology according to the present disclosure can exhibit other effects obvious to those skilled in the art from the description of the present specification together with or instead of the above effects. Note that the following configurations also belong to the technical scope of the

present disclosure.
(1) A semiconductor device including
a semiconductor substrate having a first principal surface on which a first electrode is disposed,
a first semiconductor region, of a first conductivity type, disposed on a second principal surface of the semiconductor substrate,
a plurality of second semiconductor regions, of a second conductivity type, disposed in the first semiconductor region so as to extend in parallel in a first direction,
a third semiconductor region, of the second conductivity type, disposed on the first semiconductor region,
a trench disposed in the third semiconductor region and extending in a second direction orthogonal to the first direction,
a second electrode disposed inside the trench,
a first insulating film disposed between a sidewall of the trench and the second electrode, and
a fourth semiconductor region, of the first conductivity type, disposed in the third semiconductor region, in which
the second electrode in a non-vicinity region that is a region other than a region in the vicinity of the second semiconductor region has a shallower embedment depth than the second electrode in the vicinity region.
(2)

The semiconductor device according to (1), in which, in the vicinity region, the first insulating film is further disposed between a bottom face of the trench and the second electrode.
(3)

The semiconductor device according to (2), in which, in the vicinity region, the second electrode is embedded so as to reach the first semiconductor region from the third semiconductor region.
(4)

The semiconductor device according to (3), in which, in the non-vicinity region, the second electrode is embedded so as to reach a depth of the fourth semiconductor region from the third semiconductor region.
(5)

The semiconductor device according to any one of (1) to (4), in which the second electrode has a comb-tooth shape in the second direction.
(6)

The semiconductor device according to any one of (1) to (5), in which a thickness of the third semiconductor region in the non-vicinity region is thinner than a thickness of the third semiconductor region in the vicinity region.
(7)

The semiconductor device according to (6), in which the second electrode is embedded so as to reach the first semiconductor region from the third semiconductor region in both the vicinity region and the non-vicinity region.
(8)

The semiconductor device according to any one of (1) to (7), in which an embedment depth of the first insulating film in the vicinity region and an embedment depth of the first insulating film in the non-vicinity region are the same.
(9)

The semiconductor device according to any one of (1) to (7), in which an embedment depth of the first insulating film in the non-vicinity region is shallower than an embedment depth of the first insulating film in the vicinity region.
(10)

The semiconductor device according to any one of (1) to (9), in which the second semiconductor region and the third semiconductor region are electrically connected so as to be equipotential.
(11) A semiconductor device including
a semiconductor substrate having a first surface on which a first electrode is disposed;
a first semiconductor region, of a first conductivity type, disposed on a second surface of the semiconductor substrate;
a plurality of second semiconductor regions, of a second conductivity type, disposed on the first semiconductor region and extending along a first direction;
a third semiconductor region, of the second conductivity type, disposed on the first semiconductor region, the third semiconductor region defining a portion of a trench that extends along a second direction that traverses the first direction;
a second electrode disposed in the trench;
a first insulating film disposed in the trench and between a sidewall of the third semiconductor region defining the portion of the trench and the second electrode; and
a fourth semiconductor region, of the first conductivity type, disposed on the third semiconductor region, wherein
a first portion of the second electrode has a first depth that is shallower than a second depth of a second portion of the second electrode, and the second portion of the second electrode is closer to the second semiconductor region than the first portion of the second electrode.
(12)

The semiconductor device according to (11), wherein the first insulating film is further disposed between a bottom face of the trench and the second electrode.
(13)

The semiconductor device according to (12), wherein the first semiconductor region further defines a second portion of the trench, and wherein the second portion of the second electrode extends from the portion of the trench to the second portion of the trench.
(14)

The semiconductor device according to (13), wherein the fourth semiconductor region further defines a third portion of the trench, and wherein the first portion of the second electrode and the second portion of the second electrode extend from the portion of the trench to the third portion of the trench.
(15)

The semiconductor device according to any of (11) to (14), wherein the second electrode has a comb-tooth shape in the second direction.
(16)

The semiconductor device according to any of (11) to (15), wherein a thickness of a first portion of the third semiconductor region is thinner than a thickness of a second portion the third semiconductor region, wherein the second portion of the third semiconductor region is closer to the second semiconductor region than the first portion of the third semiconductor region.
(17)

The semiconductor device according to (16), wherein the first portion of the second electrode extends from the portion of the trench to the third portion of the trench and the second portion of the second electrode extends from the portion of the trench to the second portion of the trench.
(18)

The semiconductor device according to any of (11) to (17), wherein the second electrode and the first insulating film combine to have a single thickness across a length of the trench.
(19)

The semiconductor device according to any of (11) to (18), wherein an embedment depth of the first insulating film is approximately the same across an entirety of the trench.
(20)

The semiconductor device according to any of (11) to (19), wherein the first insulating film extends to and contacts the second semiconductor region.
(21)

The semiconductor device according to any of (11) to (20), wherein the second semiconductor region and the third semiconductor region are electrically connected so as to be equipotential.
(22)

The semiconductor device according to any of (11) to (22), wherein the second electrode and the first insulating film combine to have a plurality of different thicknesses across a length of the trench.
(23) A vehicle control system including
an electronic controller including a semiconductor device.
wherein the semiconductor device includes:

a semiconductor substrate having a first surface on which a first electrode is disposed;
a first semiconductor region, of a first conductivity type, disposed on a second surface of the semiconductor substrate;
a plurality of second semiconductor regions, of a second conductivity type, disposed on the first semiconductor region and extending along a first direction;
a third semiconductor region, of the second conductivity type, disposed on the first semiconductor region, the third semiconductor region defining a portion of a trench that extends along a second direction that traverses the first direction;
a second electrode disposed in the trench;
a first insulating film disposed in the trench and between a sidewall of the third semiconductor region defining the portion of the trench and the second electrode: and
a fourth semiconductor region, of the first conductivity type, disposed on the third semiconductor region, wherein
a first portion of the second electrode has a first depth that is shallower than a second depth of a second portion of the second electrode, and
the second portion of the second electrode is closer to the second semiconductor region than the first portion of the second electrode.
(24)

The vehicle control system according to (23), wherein the first insulating film is further disposed between a bottom face of the trench and the second electrode.
(25)

The vehicle control system according to (24), wherein the first semiconductor region further defines a second portion of the trench, and wherein the second portion of the second electrode extends from the portion of the trench to the second portion of the trench.
(26)

The vehicle control system according to (25), wherein the fourth semiconductor region further defines a third portion of the trench, and wherein the first portion of the second electrode and the second portion of the second electrode extend from the portion of the trench to the third portion of the trench.
(27)

The vehicle control system according to any of (23) to (26), wherein the second electrode has a comb-tooth shape in the second direction.
(28)

The vehicle control system according to any of (23) to (27), wherein a thickness of a first portion of the third semiconductor region is thinner than a thickness of a second portion the third semiconductor region, wherein the second portion of the third semiconductor region is closer to the second semiconductor region than the first portion of the third semiconductor region.
(29)

The vehicle control system according to (28), wherein the first portion of the second electrode extends from the portion of the trench to the third portion of the trench and the second portion of the second electrode extends from the portion of the trench to the second portion of the trench.
(30)

The vehicle control system according to any of (23) to (29), wherein the second electrode and the first insulating film combine to have a single thickness across a length of the trench.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

1, 2 Semiconductor device
110 First electrode
120 Semiconductor substrate
130 First semiconductor region
131 Second semiconductor region
140 Third semiconductor region
151 Second electrode
152 First insulating film
160 Fourth semiconductor region
170 Third electrode

1. A semiconductor device comprising:
a semiconductor substrate having a first surface on which a first electrode is disposed;
a first semiconductor region, of a first conductivity type, disposed on a second surface of the semiconductor substrate;
a plurality of second semiconductor regions, of a second conductivity type, disposed on the first semiconductor region and extending along a first direction;
a third semiconductor region, of the second conductivity type, disposed on the first semiconductor region, the third semiconductor region defining a portion of a trench that extends along a second direction that traverses the first direction;
a second electrode disposed in the trench;
a first insulating film disposed in the trench and between a sidewall of the third semiconductor region defining the portion of the trench and the second electrode; and
a fourth semiconductor region, of the first conductivity type, disposed on the third semiconductor region, wherein
a first portion of the second electrode has a first depth that is shallower than a second depth of a second portion of the second electrode, and the second portion of the second electrode is closer to the second semiconductor region than the first portion of the second electrode.

2. The semiconductor device according to claim 1, wherein the first insulating film is further disposed between a bottom face of the trench and the second electrode.

3. The semiconductor device according to claim 2, wherein the first semiconductor region further defines a second portion of the trench, and wherein the second portion of the second electrode extends from the portion of the trench to the second portion of the trench.

4. The semiconductor device according to claim 3, wherein the fourth semiconductor region further defines a third portion of the trench, and wherein the first portion of the second electrode and the second portion of the second electrode extend from the portion of the trench to the third portion of the trench.

5. The semiconductor device according to claim 1, wherein the second electrode has a comb-tooth shape in the second direction.

6. The semiconductor device according to claim 1, wherein a thickness of a first portion of the third semiconductor region is thinner than a thickness of a second portion the third semiconductor region, wherein the second portion of the third semiconductor region is closer to the second semiconductor region than the first portion of the third semiconductor region.

7. The semiconductor device according to claim 6,
wherein the first portion of the second electrode extends from the portion of the trench to the third portion of the trench and the second portion of the second electrode extends from the portion of the trench to the second portion of the trench.

8. The semiconductor device according to claim 1, wherein the second electrode and the first insulating film combine to have a single thickness across a length of the trench.

9. The semiconductor device according to claim 1, wherein an embedment depth of the first insulating film is approximately the same across an entirety of the trench.

10. The semiconductor device according to claim 1, wherein the first insulating film extends to and contacts the second semiconductor region.

11. The semiconductor device according to claim 1, wherein the second semiconductor region and the third semiconductor region are electrically connected so as to be equipotential.

12. The semiconductor device according to claim 1, wherein the second electrode and the first insulating film combine to have a plurality of different thicknesses across a length of the trench.

13. A vehicle control system comprising:
an electronic controller including a semiconductor device.
wherein the semiconductor device includes:
a semiconductor substrate having a first surface on which a first electrode is disposed;
a first semiconductor region, of a first conductivity type, disposed on a second surface of the semiconductor substrate;
a plurality of second semiconductor regions, of a second conductivity type, disposed on the first semiconductor region and extending along a first direction;
a third semiconductor region, of the second conductivity type, disposed on the first semiconductor region, the third semiconductor region defining a portion of a trench that extends along a second direction that traverses the first direction;
a second electrode disposed in the trench;
a first insulating film disposed in the trench and between a sidewall of the third semiconductor region defining the portion of the trench and the second electrode; and
a fourth semiconductor region, of the first conductivity type, disposed on the third semiconductor region, wherein
a first portion of the second electrode has a first depth that is shallower than a second depth of a second portion of the second electrode, and
the second portion of the second electrode is closer to the second semiconductor region than the first portion of the second electrode.

14. The vehicle control system according to claim 13, wherein the first insulating film is further disposed between a bottom face of the trench and the second electrode.

15. The vehicle control system according to claim 14, wherein the first semiconductor region further defines a second portion of the trench, and wherein the second portion of the second electrode extends from the portion of the trench to the second portion of the trench.

16. The vehicle control system according to claim 15, wherein the fourth semiconductor region further defines a third portion of the trench, and wherein the first portion of the second electrode and the second portion of the second electrode extend from the portion of the trench to the third portion of the trench.

17. The vehicle control system according to claim 13,
wherein the second electrode has a comb-tooth shape in the second direction.

18. The vehicle control system according to claim 13, wherein a thickness of a first portion of the third semiconductor region is thinner than a thickness of a second portion the third semiconductor region, wherein the second portion of the third semiconductor region is closer to the second semiconductor region than the first portion of the third semiconductor region.

19. The vehicle control system according to claim 18.
wherein the first portion of the second electrode extends from the portion of the trench to the third portion of the trench and the second portion of the second electrode extends from the portion of the trench to the second portion of the trench.

20. The vehicle control system according to claim 13, wherein the second electrode and the first insulating film combine to have a single thickness across a length of the trench.
